(19) United States
(12) Patent Application Publication
(10) Pub. No.: US 2026/0255064 A1
(43) Pub. Date: Aug. 27, 2026

(54) SYNCHRONIZED CAMERA AND MICROPHONE TRACKING

(71) Applicant: Dell Products L.P., Round Rock, TX (US)

(72) Inventor: Peng Lip Goh, Singapore (SG)

(73) Assignee: Dell Products L.P., Round Rock, TX (US)

(21) Appl. No.: 19/060,960

(22) Filed: Feb. 24, 2025

(51) Int. Cl. H04N 23/695; G01R 33/07; G03B 17/56; H04N 23/51; H04R 1/08

(52) U.S. Cl. CPC H04N 23/695; G01R 33/072; G03B 17/561; H04N 23/51; H04R 1/08

(57) ABSTRACT

An information handling system camera coupled by a bracket to a display to capture visual images in a field of view of the camera from a viewing position of the display. A housing contains a lens and image sensor mounted by a rotating member on a mounting base. The bracket has an interior that includes an image processor to process visual images captured by the image sensor. The image sensor interfaces through a flexible cable with the image processor. A camera actuator and microphone actuator associated with the mounting base track an end user in the camera field of view with logic executing in part on the image processor.

### BACKGROUND OF THE INVENTION

### Field of the Invention

The present invention relates in general to the field of information handling system cameras, and more particularly to an information handling system synchronized camera and microphone tracking.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems process information with a processor and memory coupled in a housing. Stationary information handling system configurations, such as tower and desktop systems, have a fixed housing that interacts with external resources, such as outlet power and peripheral input/output (I/O) devices. For example, the information handling system interfaces with a peripheral keyboard, peripheral mouse and peripheral display through cables or wireless signals. Portable information handling systems integrate processing components, a display and a power source in a portable housing to support mobile operations. Portable information handling systems allow end users to carry a system between meetings, during travel, and between home and office locations so that an end user has access to processing capabilities while mobile. Portable information handling system will also typically interact with peripheral devices in the same manner as stationary information handling systems. For instance, a work area might include a docking station that the portable information handling system connects with to access peripheral device resources.

One key role for information handling systems is to act as communication tools to support personal and enterprise communications. Often, information handling systems include cameras and microphones to support videoconferencing communications. Portable information handling systems typically integrate a camera into the portable housing to capture visual images of an end user viewing the integrated display. Similarly, some peripheral display devices will integrate a camera to support videoconferencing. One difficulty with these integrated cameras is that they have a relatively small space so that the lens is restricted in size, which can impact the quality of visual images capture by the camera. As an alternative, peripheral cameras built in a housing separate from the information handling system and display tend to have more room to include a lens and other components for capture of visual images that tend to have higher quality. These peripheral cameras typically couple to a bracket that holds the camera near the display, such as by coupling to a side of the display or a stand that rests near the display.

One difficulty with peripheral cameras is that the larger form factor can present a distraction and block part of the display viewing area. In addition, components within a peripheral camera that captures quality visual images can have a relatively high cost. For a webcam that supports videoconferencing, components may include networking and logic components, such as a wireless network interface controller and a processor that supports image management like facial identification. Typically, in order to keep the camera footprint small, these components are designed to fit into a compact space. Unfortunately, this means that a failure of any component with the camera results in discarding of the camera as repairs are too difficult to accomplish.

### SUMMARY OF THE INVENTION

Therefore, a need has arisen for a system and method which separates information handling system camera components into different housing portions.

In accordance with the present invention, a system and method are provided which substantially reduce the disadvantages and problems associated with previous methods and systems for assembly of a camera. A camera has a lens and image sensor coupled in a first housing portion and interfaced by flexible cable with an image processor is a second housing portion. Separating a camera module housing and an image processor housing to assemble a camera aids in camera repair, reuse and recycling.

More specifically, an information handling system camera couples to a display with a bracket and includes a first portion having a camera module with a lens and image sensor and a second portion with an image processor. In one embodiment, the first and second portions align when the camera is nonoperational and the front portion slides relative to the rear portion when the camera is operational. An end user can readily tell the operational state of the camera by the position of the housing portions. The front portion slides from a position above a display panel to a position over the display panel when operational and with rotational and sliding movement at the bracket by the rear portion to adjust the camera field of view. In another embodiment, the bracket has a cavity that provides the housing portion for the image processor. A camera actuator interfaces with the first housing portion having the camera module to rotate towards an end user in a field of view of the camera lens. A pair of microphones coupled to the bracket interface with a microphone actuator to rotate towards the end user synchronized with the camera field of view.

The present invention provides a number of important technical advantages. One example of an important technical advantage is that a camera breaks down between a first portion that performs visual image capture and a second portion that performs image processing. The separation of these functions improves camera reuse and repair when a failure at a portion impacts camera operability. In one embodiment, a camera split body aligns the portions when in a nonoperational state and slides a portion over a display panel in an operational state so that the camera state is clear to an end user. In another embodiment, the first portion rotationally couples to a bracket second portion having a cavity that holds the image processor. The bracket portion includes microphones that rotate with the camera to have directional audio capture based upon camera rotational orientation.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of an information handling system having a peripheral camera to capture visual images in a viewing area of peripheral display;

FIG. 2 depicts an upper side perspective view of an example embodiment of a split body camera coupled to a display frame by a bracket;

FIG. 3 depicts an upper side perspective view of the example embodiment of the split body camera in an operative configuration to capture visual images;

FIG. 4 depicts a rear side perspective view of the example embodiment of the split body camera in an operational mode;

FIG. 5 depicts a rear side perspective view of the camera front housing portion exploded from the rear housing portion to illustrate example sliding members that engage in the guides;

FIGS. 6A and 6B depict a side transparent view of a transition of the camera from a non-operational configuration to an operational configuration;

FIG. 7 depicts an upper perspective transparent view of the camera in the operational position with a bracket arrangement that supports movement of the rear housing portion relative to the bracket;

FIG. 8 depicts a side sectional view of the camera in an operational configuration having the rear housing portion slid forward and tilted to adjust the camera field of view;

FIG. 9 depicts a side perspective view of the camera interior in the operational configuration with the camera housing removed;

FIG. 10 depicts a bottom transparent perspective view of the camera having the shutter biased to a blocking position by interaction of arm and housing magnets;

FIG. 11 depicts an upper perspective transparent view of the camera with the shutter motivated to move to a nonblocking position when the housing is initially slid from the nonoperational configuration to the operational configuration;

FIG. 12 depicts a lower perspective transparent view of the camera with the shutter motivated to move to a blocking position when the housing is initially slid from the operational configuration to the nonoperational configuration;

FIG. 13 depicts an alternative embodiment of the camera having a tunable lens module coupled to the camera front face;

FIG. 14 depicts an exploded perspective view of the tunable lens module;

FIG. 15 depicts one alternative embodiment having the camera treated with external and internal films by in-mold decoration to manage contaminants and moisture as illustrated by a flow diagram;

FIG. 16 depicts another alternative embodiment having the camera treated with external and internal films by out-of-mold application to manage contaminants and moisture as illustrated by a flow diagram;

FIG. 17 depicts an upper side perspective transparent view of an alternative embodiment of the split body camera;

FIGS. 18 and 18A depict a bottom perspective transparent view of the camera flexible cable interfaces between the middle printed circuit board and the image processor printed circuit board;

FIG. 19 depicts a lower perspective view of the bracket upper arm cavity having a treatment to reduce contaminants;

FIGS. 20 and 20A depict a mounting base that rotationally couples the camera housing and bracket with a treatment to reduce contaminants;

FIG. 21 depicts a side perspective transparent view of one example embodiment of the camera configured to support directional control of microphones 216 based upon an end user position in the camera field of view;

FIGS. 22 and 22A depict a rear side transparent view of an alternative embodiment of the camera configured to support directional control of the camera field of view synchronized with the microphone audio capture direction;

FIG. 23 depicts a front perspective transparent view of operation of a camera actuator synchronized with a microphone actuator to capture audiovisual of an end user in the camera field of view;

FIG. 24 depicts a flow diagram of a process for synchronizing camera and microphone rotation in a right direction;

FIG. 25 depicts a flow diagram of a process for synchronizing camera and microphone rotation in a left direction; and

FIG. 26 depicts a flow diagram of a process for managing microphone orientation based upon a camera orientation.

### DETAILED DESCRIPTION

An information handling system peripheral camera securely captures visual images at a display viewing area with a compact footprint. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

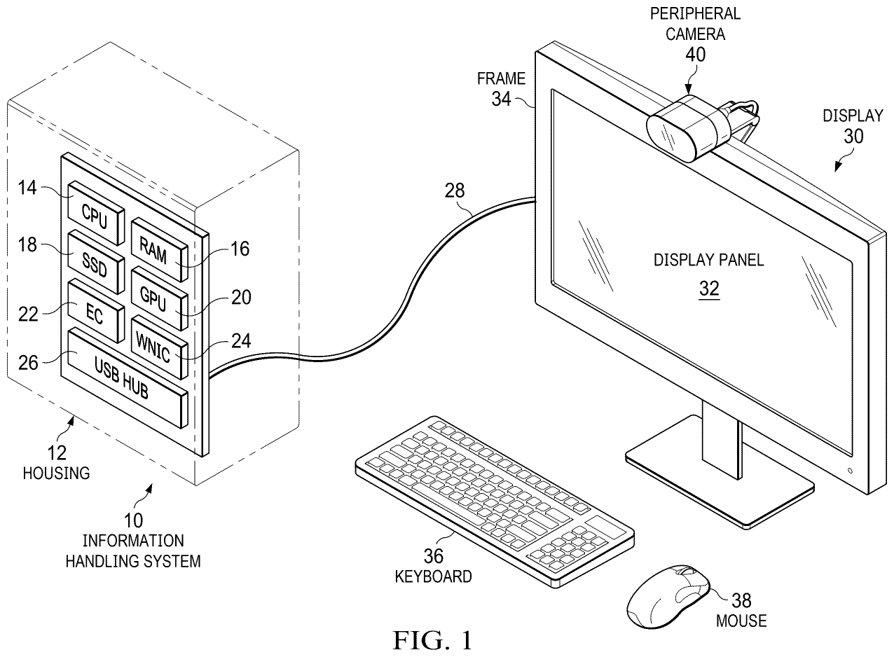

Referring now to FIG. 1, a block diagram depicts an information handling system 10 having a peripheral camera 40 to capture visual images in a viewing area of peripheral display 30. In the example embodiment, information handling system 10 has a desktop configuration with processing components contained a fixed housing 12. In alternative embodiments, a portable information handling system may be used. A central processing unit (CPU) 14 processes information by executing instructions in cooperation with a random access memory (RAM) 16 that stores the instructions and information. A solid state drive (SSD) 18 provides persistent storage of the information and instructions. A graphics processing unit (GPU) 20 interfaces with CPU 14 and further processes information to define visual images for presentation at display 30, such as by defining pixel values. An embedded controller 22 manages operating conditions with the information handling system, such as application of power and maintenance of thermal constraints. Embedded controller 22 also supports interactions with peripheral devices, such as keyboard 36 and mouse 38. A wireless network interface controller (WNIC) 24 manages network communications, such as through Ethernet, WIFI and BLUETOOTH. A USB hub 26 supports communication through USB cable 28, such as to communicate visual information to display 30.

In the example embodiment, a peripheral display 30 interfaced with information handling system 10 through a cable 28 presents visual images by scanning pixel values to an array of pixels of a display panel 32 held in a frame 34. An end user viewing display panel 32 is in a field of view of a peripheral camera 40 coupled by a bracket to frame 34 at a top side of display 30. For example, visual images captured by peripheral camera 40 are communicated to information handling system 10 to support a videoconference. In the example embodiments described below, peripheral camera 40 is a webcam that supports capture of visual images for a videoconference. To enhance repairability, the webcam breaks down between a first portion that includes a lens and image sensor and a second portion that includes an image signal processor (ISP) and other logical components to process and communicate the visual image information. By splitting the image sensor and lens from the image processor, an end user is provided with options to upgrade and repair the camera, thus reducing waste and reusing operable components.

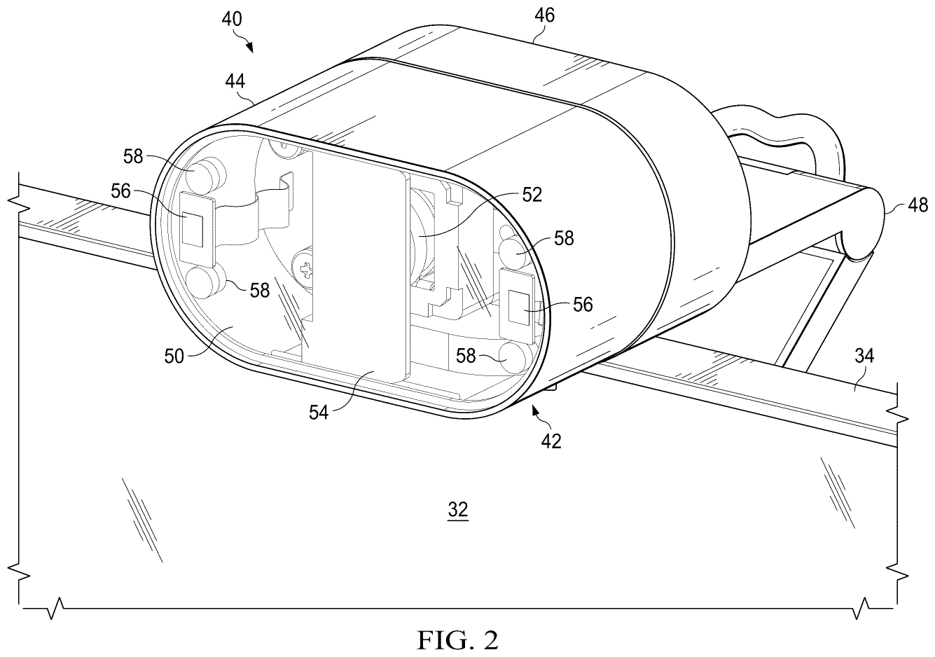

Referring now to FIG. 2, an upper side perspective view depicts an example embodiment of a split body camera 40 coupled to a display frame 34 by a bracket 48. Camera 40 is built into a housing 42 having a front housing portion 44 slidingly engaged with a rear housing portion 46. Rear housing portion 46 couples to bracket 48 so that front housing portion 44 slides to a split body configuration that extends down past frame 34 and over display panel 32. A clear cover 50 encloses front housing portion 44 that contains a camera module 52 having a lens and image sensor. In the example embodiment, alignment of the oval shaped front and rear housing portions indicates that camera 40 is disabled from capturing visual images. In this inoperative state, a shutter 54 automatically slides into position to block the camera module. The example embodiment shows a connector 56 and front cover magnets 58 that are used to selectively couple a tunable lens module to cover 50 as described in greater detail below. In the inoperative configuration shown, bracket 48 couples to frame 34 to hold camera 40 outside of the perimeter of display panel 32. A USB cable 28 couples to a port at the camera rear side to provide power and communication. Visual images captured by camera 40 may also be communicated with wireless signals, such as WIFI.

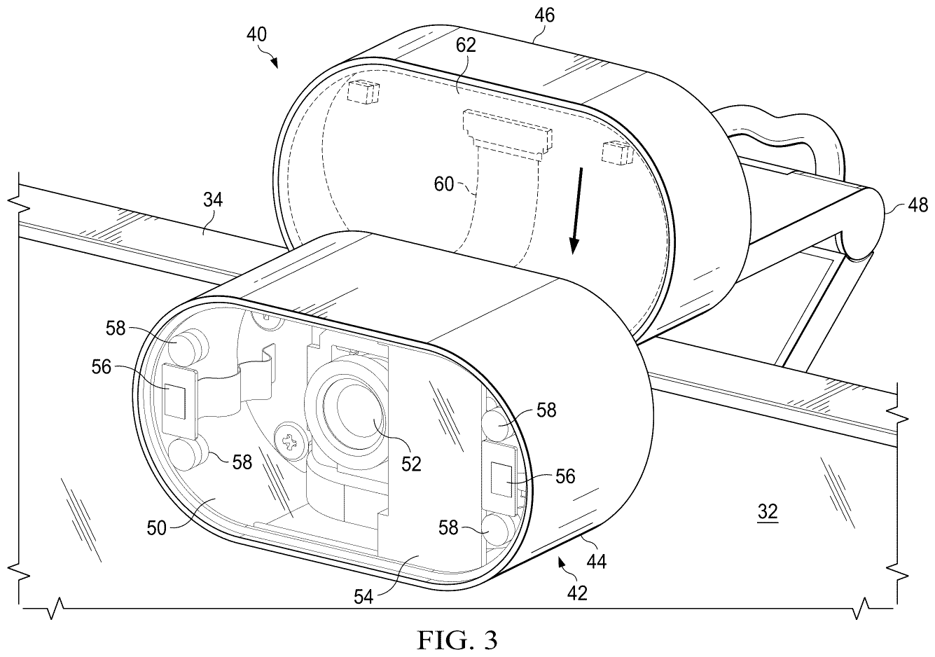

Referring now to FIG. 3, an upper side perspective view depicts the example embodiment of the split body camera 40 in an operative configuration to capture visual images. Front housing portion 44 has slid downward relative to rear housing portion 46 so that an end user viewing housing 42 can readily tell that camera 40 is operational. Camera module 52 is exposed by sliding of shutter 54 to one side automatically as front housing portion 44 slides down relative to rear housing portion 46. The lower position of front housing portion 44 places camera module 52 in a lower position that is more level with an end user's eyes and covers a portion of display panel 32 so that the end user is on notice that the camera is operational. Rear housing portion 46 has an opaque cover 62 that hides components to support operation of the camera module in the front housing portion. For example, a flexible cable 60, such as a flexible printed circuit, interfaces the camera module in the first housing portion with an image processor operating in the second housing portion. Distributing the lens and image sensor separate from the image processor aids in having reuse of the separated components in the event of a camera failure or upgrade.

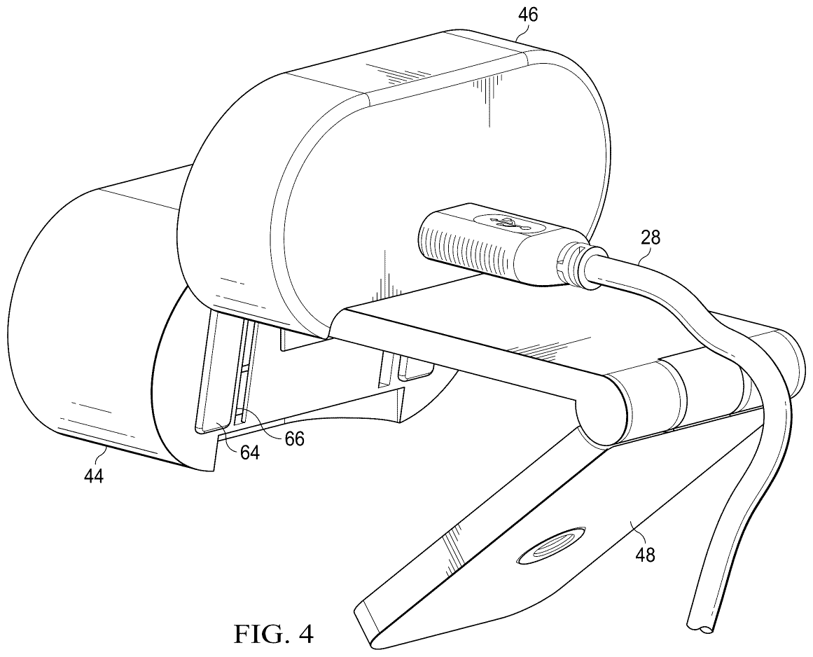

Referring now to FIG. 4, a rear side perspective view depicts the example embodiment of the split body camera in an operational mode. Two parallel guides 66 formed in the rear side of front housing portion 44 engage with a member extending from a front side of rear housing portion 46 to slide to the operational configuration. A friction pad 64, such as mylar, reduces the friction between the housing portions during the sliding. Bracket 48 has rear housing portion 46 coupled to an upper side while front housing portion slides downward in front of the bracket and the display panel. A USB cable 28 fits into a port at the rear side of rear housing portion 46 to provide power and data transfer at camera 40. Split down of housing portions to place camera 40 in the operational mode makes the operational mode apparent to an end user even at some distance from the camera.

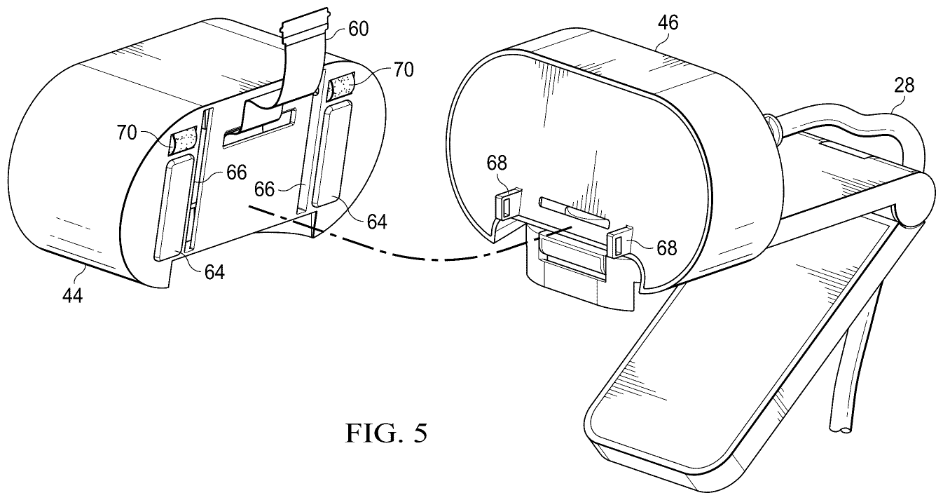

Referring now to FIG. 5, a rear side perspective view depicts the camera front housing portion 44 exploded from the rear housing portion 46 to illustrate example sliding guide members 68 that engage in guides 66. A slot between guide members 68 accepts the flexible cable 60 to communicate visual image information from an image sensor in front housing portion 44 to an image processor in rear housing portion 46. Friction pads 64 press against rear housing portion 46 to reduce friction associated with sliding motion against rear housing portion 46. Power to run the camera components is provided through USB cable 28 in rear housing portion 46 and then communicated through flexible cable 60 to front housing portion 44. As is described in greater detail below, a magnetic roller 70 extends out an opening of the rear side of front housing portion to engage against the front of rear housing portion 46 to control movement between the operational configuration and nonoperational configuration of the camera.

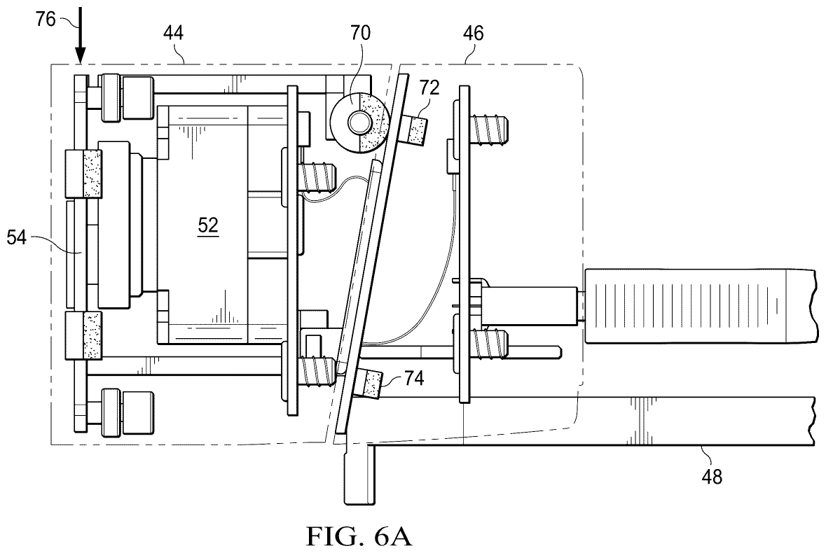

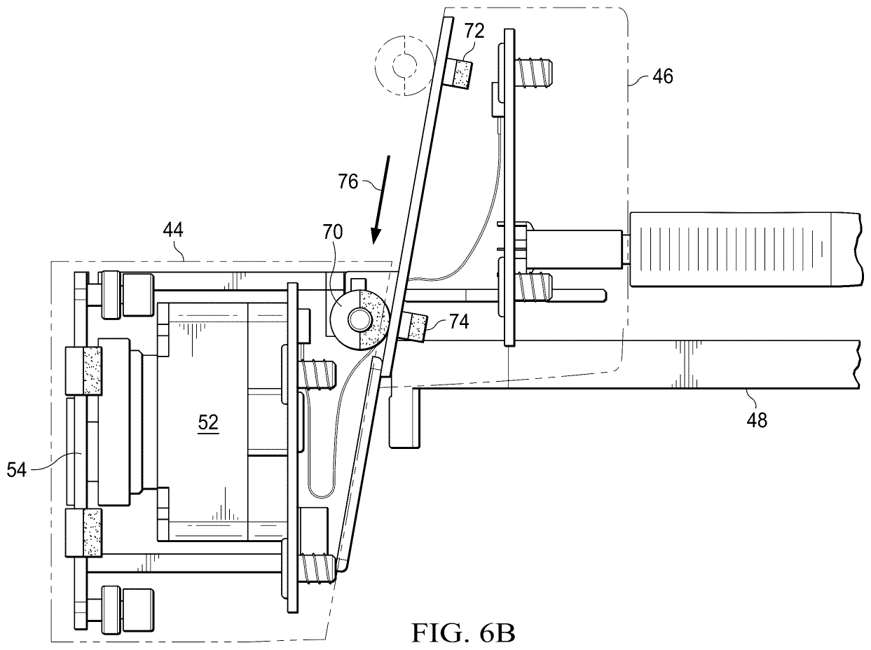

Referring now to FIGS. 6A and 6B, a side transparent view depicts a transition of the camera from a non-operational configuration to an operational configuration. FIG. 6A depicts the camera in the nonoperational configuration having the front housing portion 44 oval-shaped perimeter aligned with the rear housing portion 46 oval-shaped perimeter. Camera module 52 is blocked by shutter 54 and magnetic roller 70 is attracted to a magnet 72 coupled in a fixed location at the upper side of rear housing portion 46. Magnetic roller 70 has a round shape on an axle to roll when pressed against the rear housing portion. Magnetic attraction of magnetic roller 70 to upper magnet 72 holds the front and rear housing portions in alignment. In the example embodiment, an end user press down in the direction of arrow 76 to overcome the magnetic attraction of magnetic roller 70 and the upper magnet 72 so that the front housing portion slides downward as indicated by arrow 76 in FIG. 6B. The sliding motion of front housing portion 44 has less resistance once the magnetic attraction is overcome as the front housing portion moves downward below the level of bracket 48 and in front of the display panel. Once magnetic roller 70 approaches a bottom magnet 74 coupled in rear housing portion 46, the magnetic attraction holds front housing portion 44 in the operational position. As front housing portion 44 reaches the operational position, shutter 54 automatically slides from a blocking position to an unblocking position to expose camera module 52 for capture of visual images.

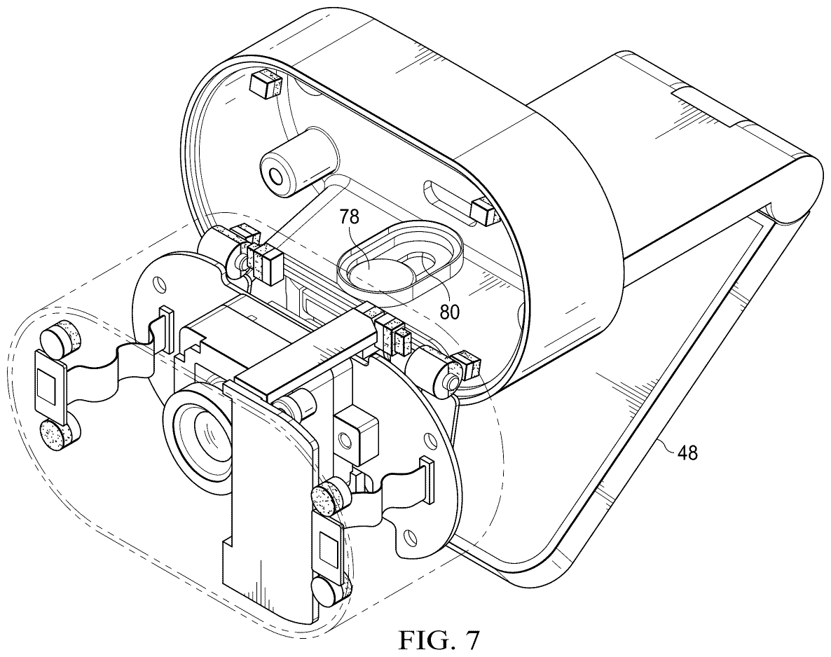

Referring now to FIG. 7, an upper perspective transparent view depicts the camera in the operational position with a bracket arrangement that supports movement of the rear housing portion relative to the bracket. In the example embodiment, housing rear portion 46 couples to bracket 48 with a sliding pin 78 that engages bracket 48 through a slot 80. Rear housing portion 46 slides relative to bracket 48 based upon the pin and slot defined motion so that the rear housing portion can slide forward relative to the display frame while the bracket engages at a fixed position relative to the display frame. This sliding distance provides additional spacing between the rear side of front housing portion 44 and the display panel when the front housing portion slides downwards and in front of the display panel.

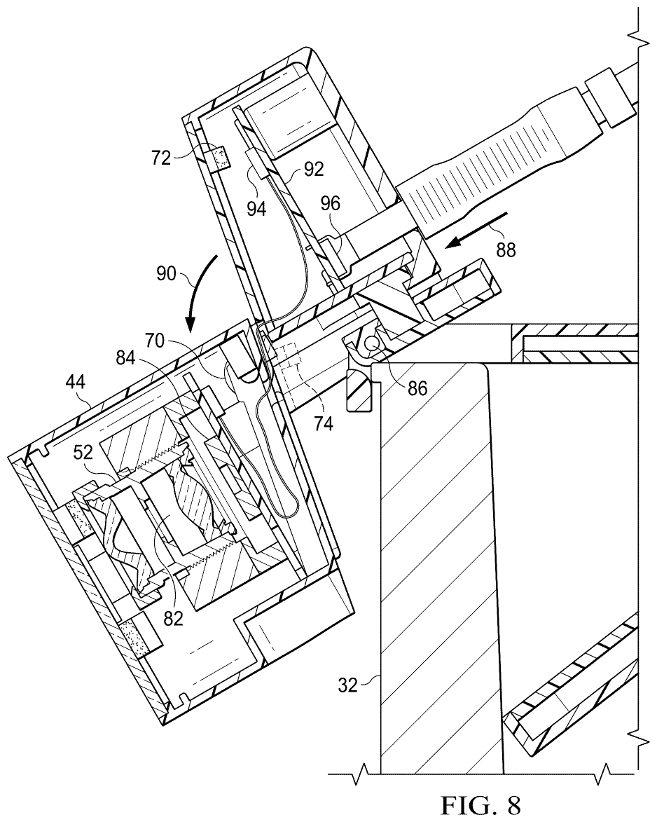

Referring now to FIG. 8, a side sectional view depicts the camera in an operational configuration having the rear housing portion 46 slid forward and tilted to adjust the camera field of view. In the example embodiment, housing front portion 44 and camera module 52 captures visual images at a field of view of a lens 82 that directs light to an image sensor 84 when slid by magnetic roller 70 to a lower position aligned with lower magnet 74. Bracket 48 couples to housing rear portion 46 at a hinge 86 so that a forward sliding motion of arrow 88 by the pin and slot arrangement and a rotation about the hinge 86 by arrow 90 rotates the camera field of view downward to be directed at an end user viewing a central portion of display 32. A printed circuit board 92 coupled in housing rear portion 46 supports an image processor 94, such as an ISP, to receive visual images from image sensor 84 and communicate the visual images out from the camera through a USB hub 96. The forward sliding and rotation of housing rear portion 46 provides additional spacing between the housing front portion 44 and display 32 while adjusting the camera field of view.

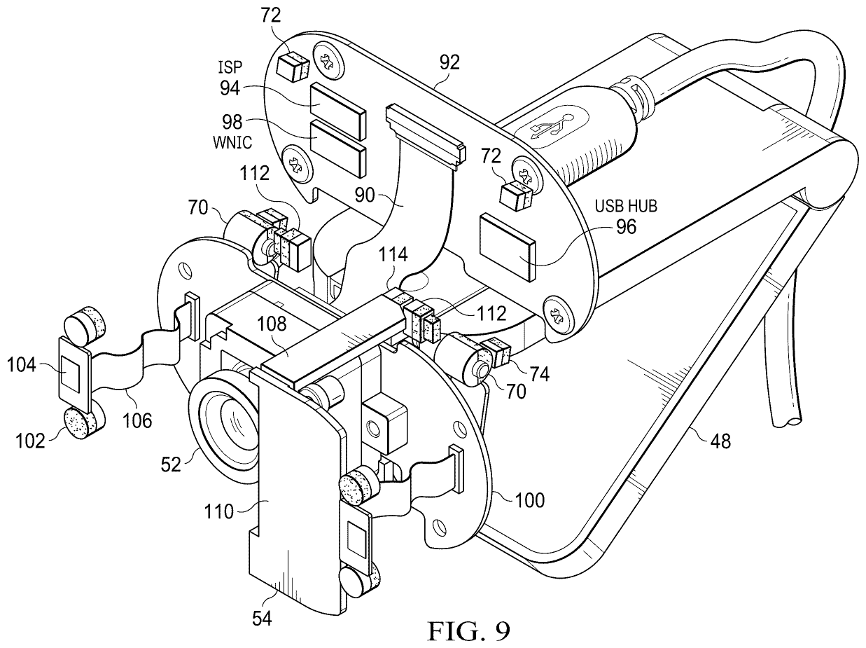

Referring now to FIG. 9, a side perspective view depicts the camera interior in the operational configuration with the camera housing removed. In the example embodiment, an image processor 94 couples to a printed circuit board 92 of the housing rear portion to manage image processing functions, such as visual image compression and facial identification. A pair of magnets 72 at an upper side of printed circuit board 92 couple to magnetic roller 74 in the nonoperational housing configuration. A USB hub 96 manages power and communication with external devices through the USB cable. A flexible cable 90 couples to printed circuit board 92 to interface power and visual image information with the camera module 52 that couples to an image sensor printed circuit board 100 of the housing front portion. A wireless network interface controller 98 interfaces with image processor 94 to support wireless communication of visual image information. Image sensor printed circuit board 100 interfaces through a flexible cable 106 with a connector 104 that supports an interface with a tunable lens module coupled by magnetic attraction to magnets 102 as described in greater detail below.

In the example embodiment, shutter 54 couples in the housing front portion to automatically slide between blocking and unblocking positions at camera module 52 when the front portion slides between nonoperational and operational configurations. Shutter 54 has a planar front portion 110 that slides in front of camera module 52 to block visual image capture and to one side to allow visual image capture. A top and bottom arm 108 from planar front portion 110 to image sensor printed circuit board 100 interfaces magnets 114 coupled to arms 108 with magnets 112 coupled to the rear side of the housing front portion. Magnet 114 on the upper arm 108 has an opposite polarity to magnets 114 coupled to the bottom arm 108 so that magnetic attraction pulls shutter 54 to the unblocked position when the upper arm aligns with magnets 112 and pulls shutter 54 to the blocked position when the lower arm aligns with magnets 112.

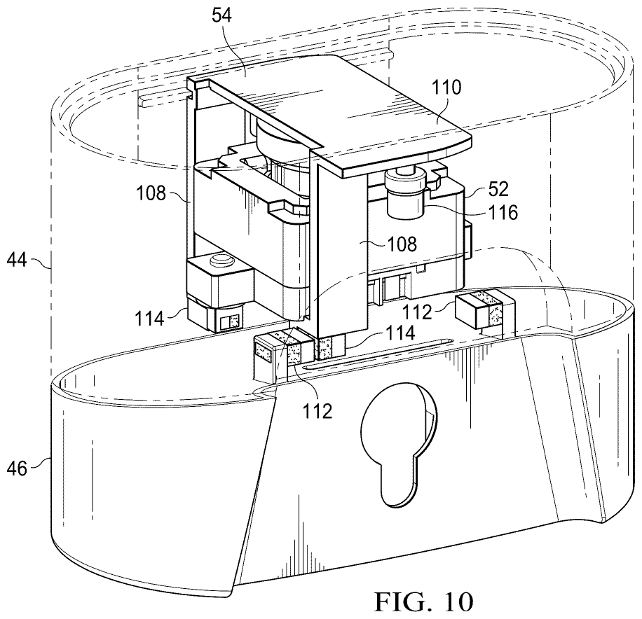

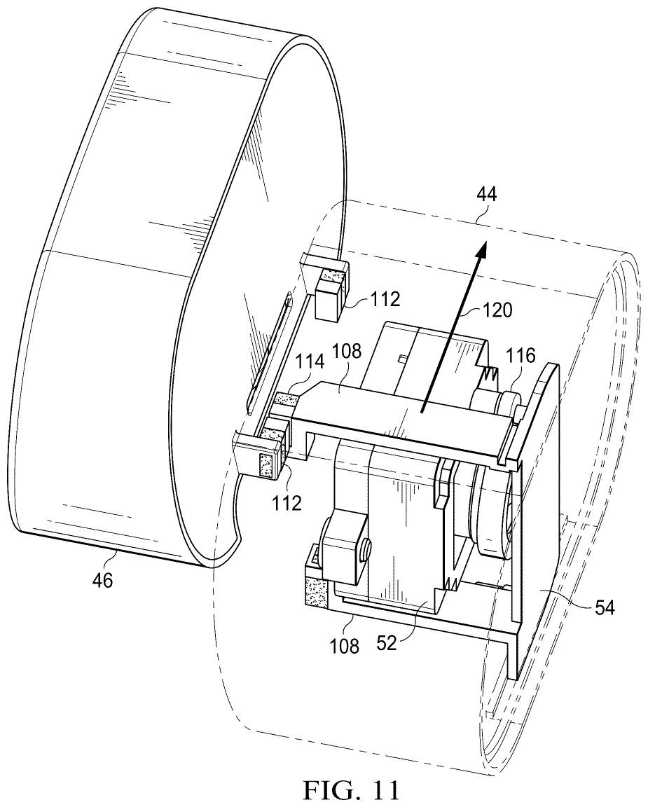

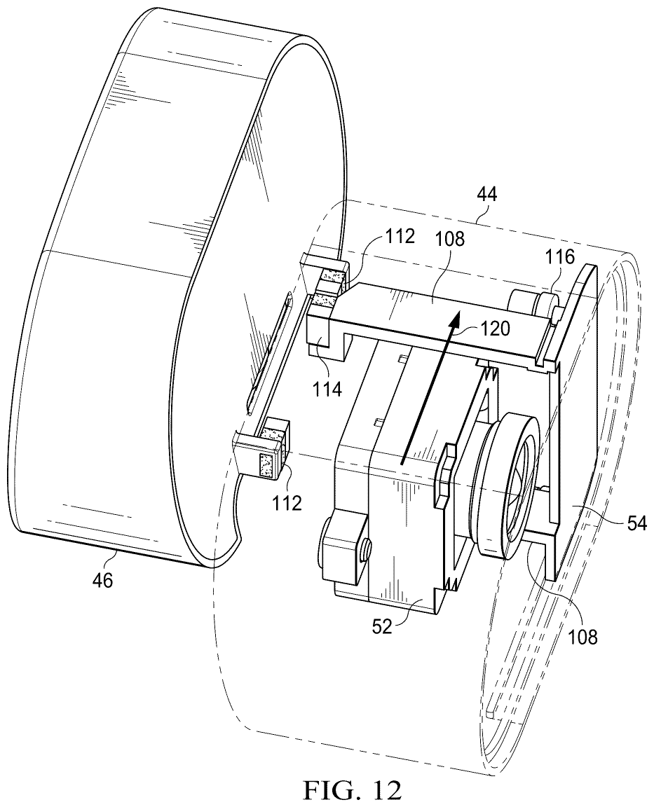

Referring now to FIG. 10, a bottom transparent perspective view of the camera depicts the shutter biased to a blocking position by interaction of arm and housing magnets. Shutter 54 has a front planar portion 110 that slides over camera module 52 to block capture of visual images. A pair of arms 108 hold planar portion 110 in position and have magnets 114 at the end of the arm opposite planar portion 110 and aligned with housing rear side magnets 112. A shutter wheel bearing 116 rolls along the inner surface of housing front portion 44 to aid in the sliding motion of shutter 54 between blocking and unblocking positions. The upper and lower sides of planar portion 110 may engage in a slot formed in the housing front portion. The polarity of magnets 112 and 114 are arranged to attract shutter 54 to the blocking position when the housing front portion 44 and rear portion 46. In addition, magnets 112 and 114 are arranged to repel shutter 54 to the blocking position when the housing front and rear portions move from the operational position to the nonoperational position and the shutter is in the nonblocking position, as is shown in greater detail by FIGS. 11 and 12 described below.

Referring now to FIG. 11, an upper perspective transparent view depicts the camera with the shutter motivated to move to a nonblocking position when the housing is initially slid from the nonoperational configuration to the operational configuration. When housing front portion 44 is pressed down relative to housing rear portion 46 shutter 54 starts in a blocking position. Magnets 114 at the end of arm 108 are arranged to match the polarity of magnet 112 coupled to housing rear portion 46, such as the guide members insert in the guide slot. The matching polarity generates a repelling force that biases the shutter towards the unblocking position. As the shutter initiates a sliding motion supported by shutter wheel bearing 116, the distal set of magnets 112 are arranged with an opposite polarity to magnets 114 so that an attraction force pulls shutter 54 towards the unblocking position as indicated by arrow 120.

Referring now to FIG. 12, an upper perspective transparent view depicts the camera with the shutter motivated to move to a blocking position when the housing is initially slid from the operational configuration to the nonoperational configuration. When housing front portion 44 is pressed upwards, shutter 54 is initially in the unblocking position as shown. Upward sliding of housing front portion to the nonoperational position results in magnets 114 on the lower arm 108 to come into alignment with magnets 112 of the housing rear portion. The lower arm magnets and the housing rear portion magnets align with like polarities so that shutter 54 is motivated to slide towards the blocking position. The lower arm magnets 114 have opposing polarities to the housing rear portion magnets of the blocking position, resulting in a magnetic attraction that pulls the shutter to the blocking position. The arrangement of magnet polarities for magnets 112 and 114 ensure that repelling and attracting magnetic forces drive shutter 54 to change between blocking and unblocking positions each time housing front portion 44 slides between operational and nonoperational configurations.

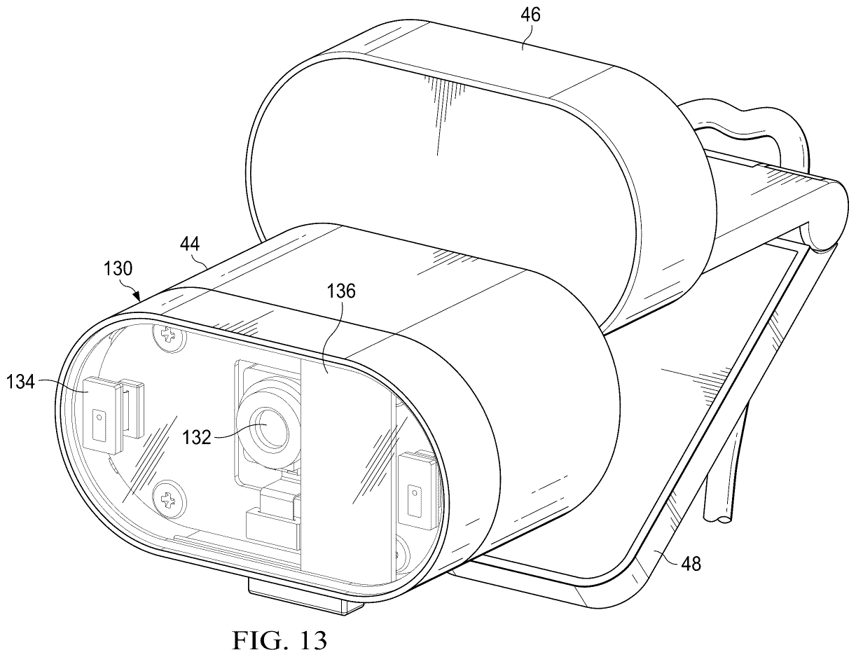

Referring now to FIG. 13, an alternative embodiment of the camera is depicted having a tunable lens module 130 coupled to the camera front face. In the example embodiment, housing front portion 44 has slid down housing rear portion 46 to an operational position as described above. Bracket 48 holds the camera at a display frame to capture visual images from a viewing area of a display. The lens and image sensor in housing front portion 44 capture visual images with a set of optical properties that define a field of view. Changing optical properties of the lens and image sensor can be done by replacing the housing front portion 44 with a different lens and image sensor configuration. Instead, the tunable lens module offers a readily assembled and removeable option that adapts the existing lens and image sensor to a wider extent of lens settings with a tunable lens 132. The tunable lens is assembled in its own housing and magnetically couples to the front side of housing front portion 44 aligned with a connector to communicate between the tunable lens and logical elements in housing rear portion 46 through the housing front portion. A microphone 134 is exposed at the front side of tunable module 130 to capture audible sounds. Tunable lens 132 is, for instance, an Optotune tunable lens that uses a combination of optical fluids and a polymer membrane to adjust between convex and concave configurations. A circular ring pushes on the center of the membrane to shape the tunable lens so that deflection of the membrane adjusts the optical qualities of the tunable lens. A shutter 136 couples in front of tunable lens 132 to slide between blocking and unblocking positions as described above.

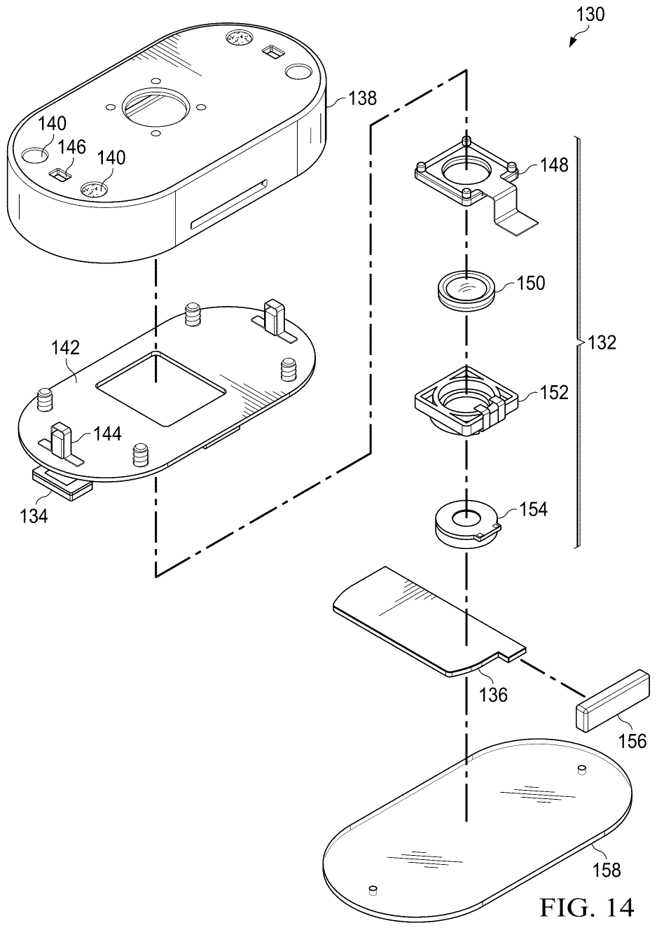

Referring now to FIG. 14, an exploded perspective view depicts the tunable lens module 130. An exterior housing 138 includes magnets 140 and an electrical connector 146 that couple with magnets and a connector of the housing front portion as described above. A printed circuit board 142 has members 144 that extend out a back slot to contact the front side of housing front portion for communication with housing rear portion. Microphone 134 is exposed at a front side of tunable lens module 130 to receive audible sounds that are communicated through electrical connector 146 to the housing front portion. Tunable lens 132 has an outer frame 148 with a cable interface, a diaphragm 150, an inner frame 152 and a tunable lens 154 that adjust shape to change its optical characteristics. A shutter 136 slides in a shutter mount 156 to block and unblock the tunable lens. A clear cover 158 encloses the tunable lens assembly.

In operation, when an end user desires an extended range for the camera field of view, the end user couples tunable lens module 130 to the housing front portion with alignment of the magnets. When tunable lens module 130 is in a neutral state, the camera operates nominally the same as when the tunable lens module is not coupled in place. When an expanded field of view is desired, the tunable lens assumes a concave to a convex form to adjust light that passed to the camera module, which manages focus of the altered light to achieve capture of the visual images. The image processor in the housing rear portion commands the tunable lens to a desired focus based on detected visual images and/or end user preferences.

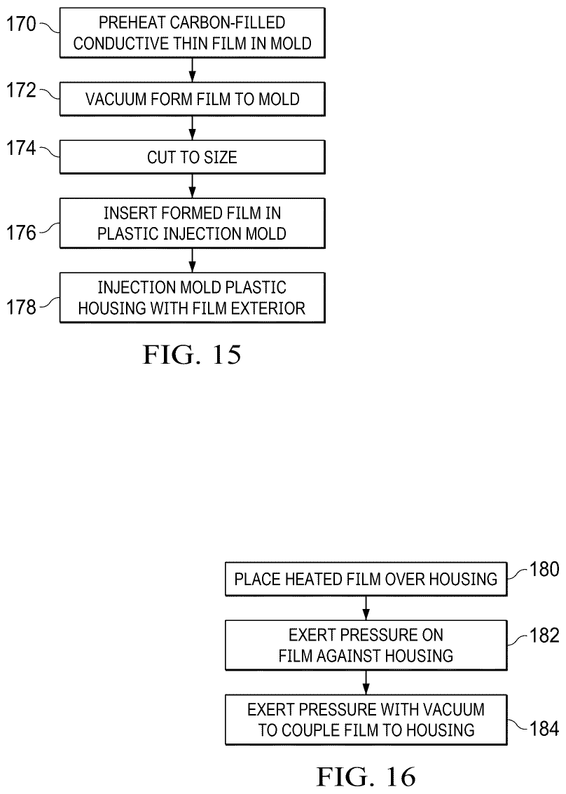

Referring now to FIG. 15, in one alternative embodiment, the camera is treated with external and internal films by in-mold decoration to manage contaminants and moisture as illustrated by a flow diagram. As is described below, the film applied to the camera housing may include an anti-static film, such as a carbon conductive thin polyethylene film, and a moisture control file, such as a microporous polyurethane or a polyester membrane. The in-mold process starts at step 170, using the carbon-filled conductive film as an example, with preheat of the carbon-filled conductive thin film in the mold. At step 172, once the film is heated, a vacuum is applied to form the film to the mold. At step 174 the edges of the film are cut to size for use in the injection mold. At step 176, the vacuum-formed film is inserted into the plastic injection mold. At step 178, injection molding forms the plastic housing with the film on the exterior. In another example, a moisture control film may be used to couple at a housing interior as described below in greater detail. Generally, the technique of in-mold decoration may include a variety of different approaches that include in-mold roller, in-mold transfer, in-mold label, and in mold forming.

Referring now to FIG. 16, in another alternative embodiment the camera is treated with external and internal films by out-of-mold application to manage contaminants and moisture as illustrated by a flow diagram. The process starts at step 180 by placing the heated film over the housing to be treated. At step 182, pressure is exerted on the film to press the film against the housing. At step 184, pressure is exerted with a vacuum to couple the film to the housing. As described above, both anti-static and moisture control films may be applied to an interior or an exterior of the housing, although the out-of-mold process is performed after the housing is formed. In various other embodiments, the film may be applied in other ways, such as with an adhesive or similar techniques.

As a first example of a film applied to a housing, a conductive carbon thin polyethylene film is coupled over the exterior of plastic housing portions with heat and an in-mold decoration process. The film over the housing exterior reduces dust and moisture attraction to the housing so that accumulations made over time do not lead to camera failure. As an example, one conductive carbon thin PE film is VELCSTAT 1700 series film from SCS, which offers an opaque, volume-conductive carbon-impregnated polyolefin material. The anti-static film applies to reduce charge build up that can attract dust and other particles.

As a second example of a film applied to a housing, an inner wall of a housing is lined with a microporous material, such as a polyurethane or polyester membrane or film. The microporous material has pores small enough to prevent moisture from entering the housing but large enough for air to pass through. In addition, gaps between housing portions may be sealed with sponge, foam or gasket formed of the microporous material. These treatments prevent moisture from entering into the housing while allowing heat and hot air to escape. As an example, RUBYCELL by TOYOPOLYMER is a urethan sponge with a fine homogeneous microporous structure have pore diameters adjustable between 10 and 300 microns. Other types of materials are available from BONTON TEC CO. LTD., and NAM LIONG GLOBAL CORP.

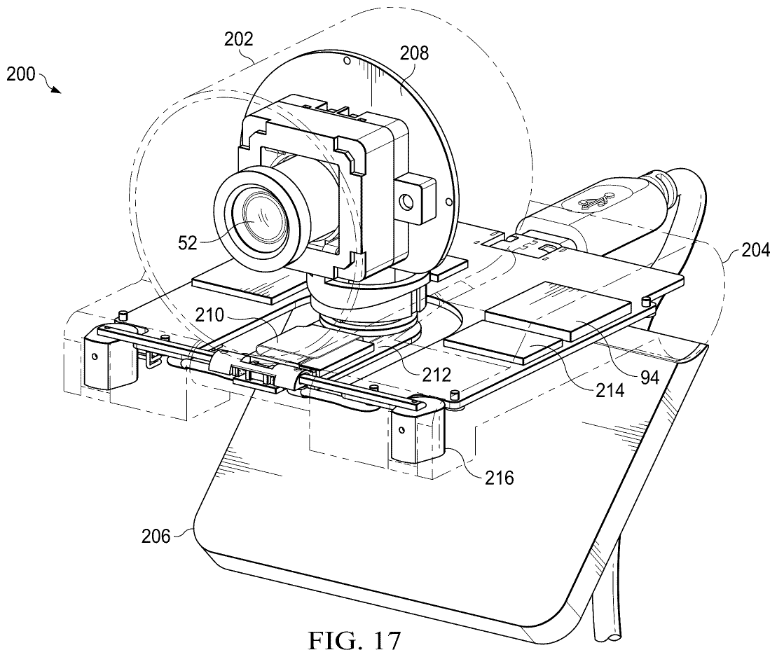

Referring now to FIG. 17, an upper side perspective transparent view depicts an alternative embodiment of the split body camera 200. The alternative embodiment includes separate housing portions similar to embodiment previously described above, with one housing portion housing the lens and image sensor and the other housing portion housing the image processor and related logical and communication components. This arrangement aids in camera repair and recycling while offering a compact and powerful system. In the example embodiment, camera 200 has a cylinder shaped camera module housing portion 202 with a camera module 52 coupled to a visual sensor printed circuit board 208 arranged normal the field of view. Housing 202 rotationally couples to a mounting base that includes a middle printed circuit board 212 interfaced with visual sensor printed circuit board 208 through a flexible cable 210, such as a flexible printed circuit. A bracket 206 has a hinge to couple an upper arm 204 and lower arm to a display frame as described above. The upper arm 204 of bracket 206 forms a cavity that holds an image processor 94 coupled to a printed circuit board 214. A pair of microphones 216 couple in the cavity of bracket 206 upper arm 204 at opposite sides of the middle printed circuit board 212 to capture audio.

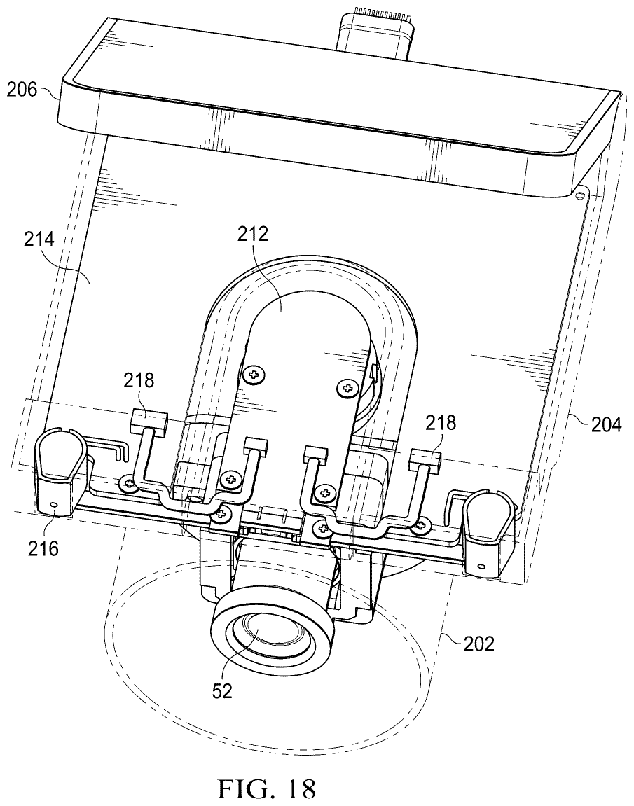

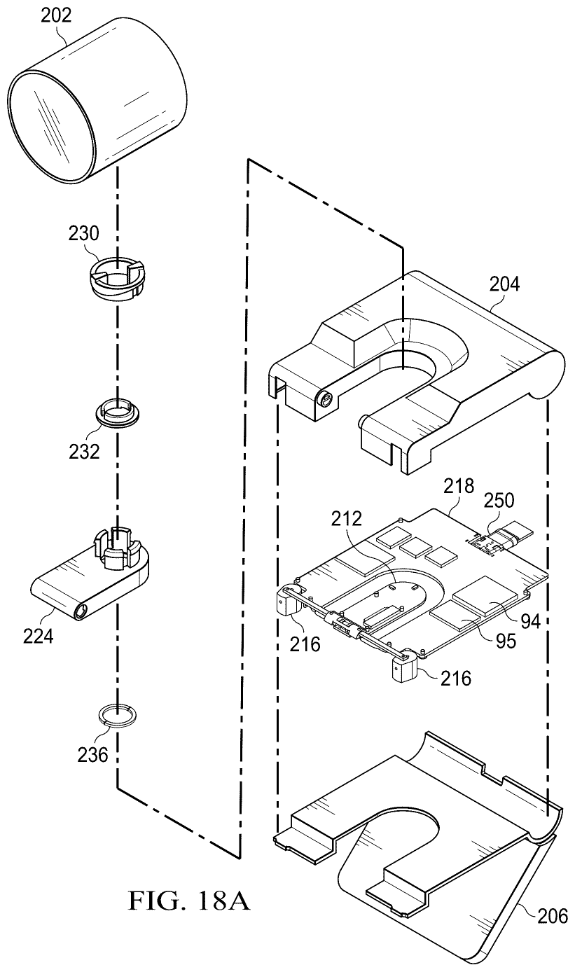

Referring now to FIGS. 18 and 18A, a bottom perspective transparent view depicts the camera flexible cable interfaces between the middle printed circuit board 212 and the image processor printed circuit board 214. A pair of flexible cables 218 communicate information between the middle printed circuit board 212 and the image processor printed circuit board 214 coupled in the cavity of bracket 206 upper arm 204. For example, camera module 52 captures visual images with an image sensor and communicates the visual images to an image processor through flexible cables 218 for processing, such as compression, facial identification and other logical functions performed by image processors. Microphones 216 capture audio that is provided to the image processor for integration and synchronization with the visual images. Operational commands to camera module are communicated from the image processor through the flexible cables to the camera module in housing 202. The image processor controls camera functions that can include power, focus and visual image capture parameters.

FIG. 18A depicts the camera in a side perspective exploded view that illustrates rotational coupling of a camera module housing portion 202 to bracket 206. A mounting base 224 has an upper rotational coupling member that couples by a connecting neck 230 with a lock ring 232 so that housing portion 202 rotates relative to mounting base 224. A circular magnet 236 rotates with the housing portion to provide a sensor reference of the housing portion rotational orientation as described below in greater detail. Bracket 206 couples to upper arm 204 to capture image processor printed circuit board 218 within the bracket cavity defined by upper arm 204. Mounting base 224 couples by an axle to upper arm 204 to rotate within the central area of upper arm 204, such as to change the elevation of the camera field of view. A middle printed circuit board 212 couples in mounting base 224 and interfaces with the image processor printed circuit board 218 by flexible cables as described above. An image processor 94 and flash memory 95 couple to the image processor printed circuit board to execute instructions that manage camera operations. Other components include a USB hub to support communication through USB port 250, a wireless network interface controller (WNIC) to communicate by WIFI and BLUETOOTH and various microcontroller units (MCUs) and other processing resources for managing camera operations. In addition, an audio processor may be included to manage audio information captured by the microphones, such as by performing analysis on sounds captured by the microphones to detect an end user speaker position within the camera field of view.

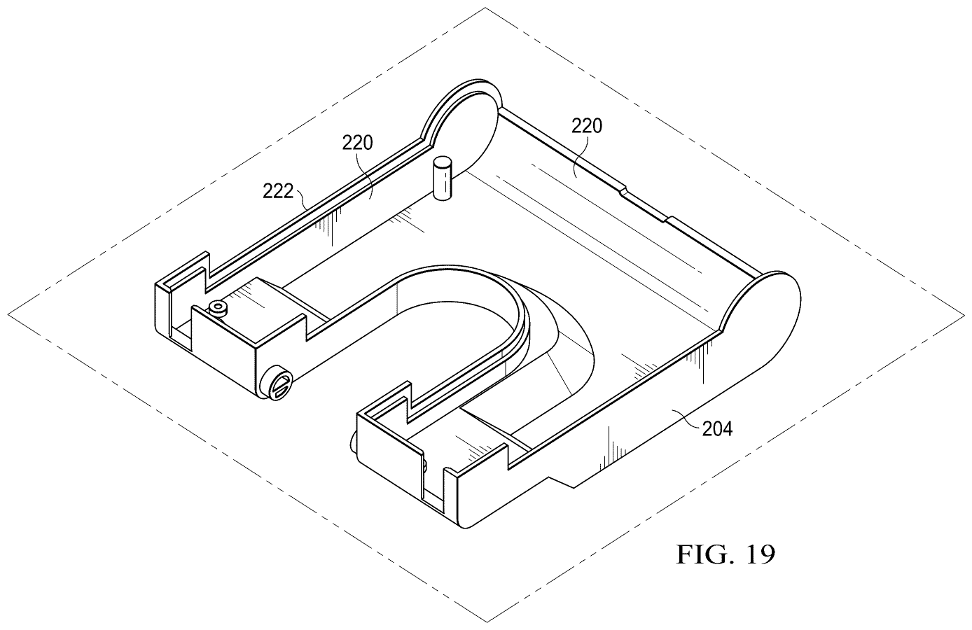

Referring now to FIG. 19, a lower perspective view depicts the bracket upper arm 204 cavity having a treatment to reduce contaminants. In the example embodiment, an inner wall of the cavity is treated with a conductive carbon thin film 220 that reduces or eliminates static charge so that dust does not accumulate. A similar carbon thin film may also be applied to the exterior of the bracket upper arm and the cylindrical housing as described above. Alternatively, the inner wall may be treated with a microporous membrane film that helps to prevent liquid water infiltration while allowing water vapor to escape as described above. In addition, a microporous sponge foam gasket 222 is coupled around the perimeter of the cavity defined by the inner wall to seal out liquid moisture while all allowing water vapor to escape to external the cavity.

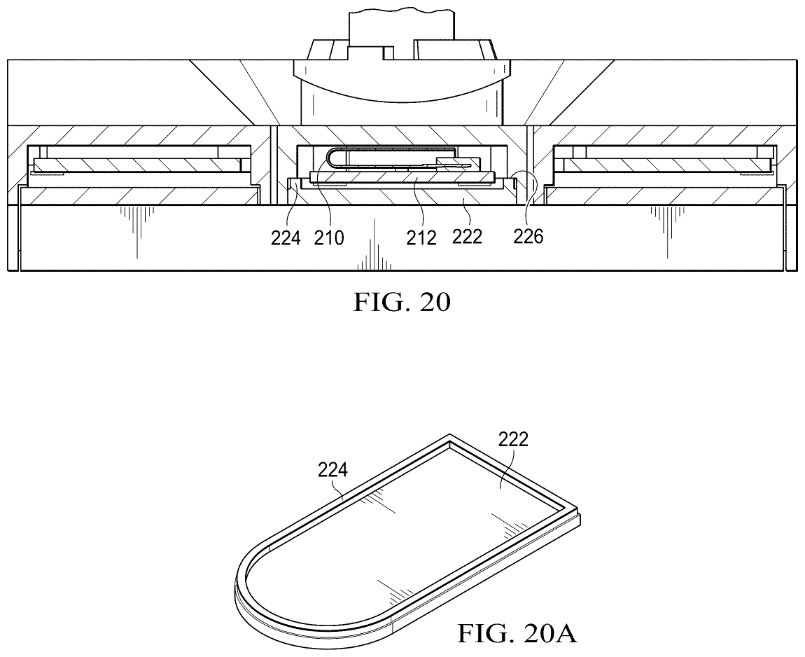

Referring now to FIGS. 20 and 20A, a mounting base 224 is depicted that rotationally couples the camera housing and bracket with a treatment to reduce contaminants. FIG. 20 depicts a side sectional view of mounting base 224 enclosing middle circuit board 212 and flexible cable 210 against the base 226 of the camera module housing 202 and a rotational neck described below. FIG. 20A depicts an upper perspective view of mounting base 224 with a microporous sponge foam gasket 222 around its perimeter to prevent liquid water from entering while allowing vapor water to escape. FIG. 20 depicts that the vapor escapes around the perimeter through the gasket 222 while moisture in liquid form is prevented from ingress into the cavity defined by mounting base 224.

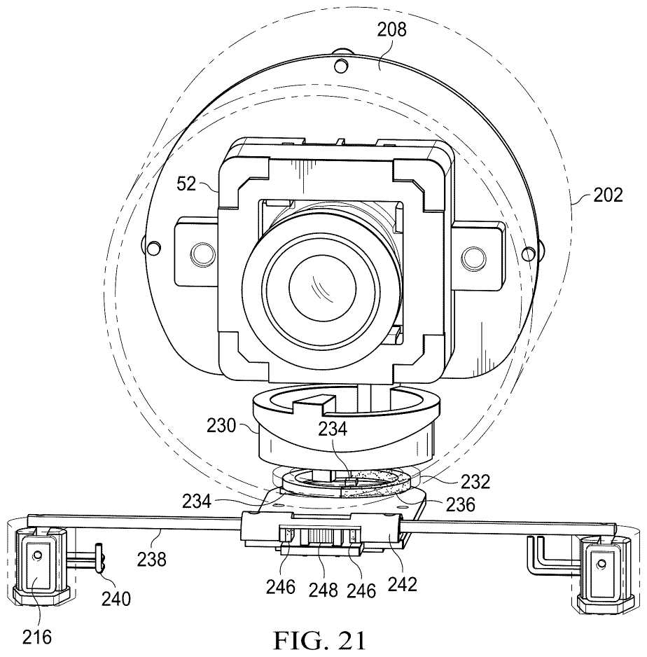

Referring now to FIG. 21, a side perspective transparent view depicts one example embodiment of the camera configured to support directional control of microphones 216 based upon an end user position in the camera field of view. Camera module housing portion 202 rotates relative to the bracket housing portion as described above so that the field of view of camera module 52 changes with changes to the housing rotational orientation. In the example embodiment, camera module 52 couples in a fixed position relative to housing portion 202 at a camera module printed circuit board 208 aligned normal the camera module field of view. In alternative embodiments, the camera module may rotate within the camera housing to change the rotational orientation of the field of view. The rotation may be automated or manual, such as by an end user manually rotating housing portion 202. Alternatively, camera module 52 may be fixed relative to the bracket without rotation while directional control of microphones 216 is applied to change the microphone direction within the field of view, such as based upon a direction to an end user speaker. In one example embodiment, direction to a speaker is determined by an audio processor so that the camera field of view may be rotated to that orientation.

In the example embodiment, circular magnet 236 rotates with the housing portion 202 relative to the middle printed circuit board 212, which is detected by Hall sensors 234 coupled to the middle printed circuit board. The rotational orientation determined from the circular magnet position is applied to determine the rotational orientation of the camera field of view so that a microphone actuator 242 can direct the microphones 216 in the direction of the field of view. In the example embodiment, the microphone actuator is an electromagnet 248 interfaced with the middle circuit board that generates a magnetic field to interact with opposing permanent magnets 246 coupled to a connecting pushrod 238. Each microphone 216 is rotationally coupled to the connecting pushrod and has a fixing arm 240 coupled to the bracket housing so that lateral movement of connecting pushrod 238 translates to rotation of microphones 216. The current applied to electromagnet 248 to achieve a desired microphone rotation may be generated by logic executing on a processing resource of the image processor printed circuit board, such as the image processor and/or audio processor. Alternatively, current applied may be proportional to the rotational orientation or other position based automated signal.

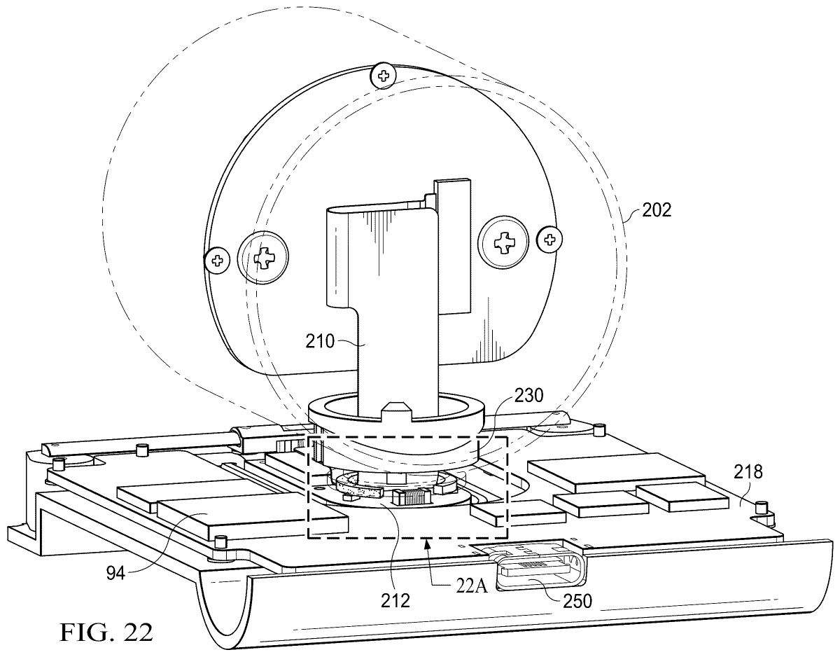

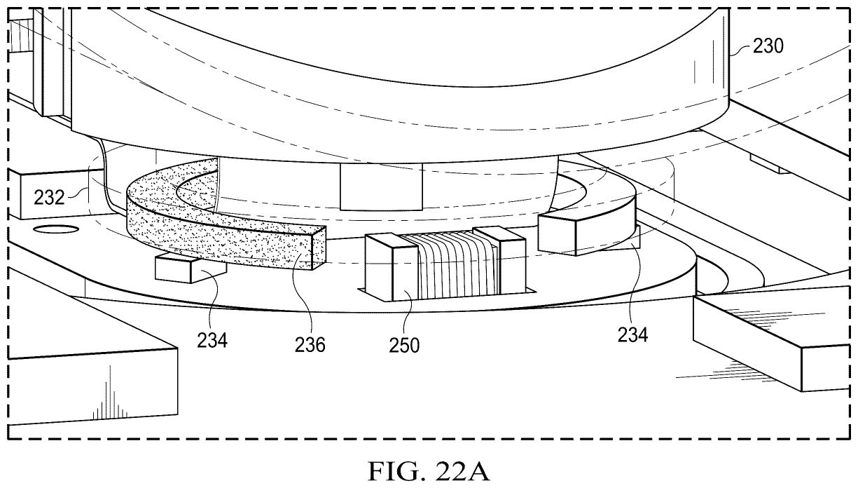

Referring now to FIGS. 22 and 22A, a rear side transparent view depicts an alternative embodiment of the camera configured to support directional control of the camera field of view synchronized with the microphone audio capture direction. FIG. 22 depicts camera module housing portion 202 interfaced by a flexible cable 210 with middle circuit board 212 and rotationally mounted to rotate relative to the bracket housing portion. An image processor 94 coupled to image processor printed circuit board 218 receives visual images captured by the camera module and communicates the visual images out a USB port 250. Image processor 94 analyzes visual images captured by the camera module to determine the location of an end user in the visual image and then applies the location information to generate command to a camera actuator to rotate housing portion 202 to center the camera field of view on the end user. In one example embodiment, the camera field of view may also be managed by a direction of detect end user speech, such as to select a speaker in the field of view to center upon. FIG. 22A depicts a detailed view of the camera actuator that rotates housing portion 202 relative to the bracket housing portion. Lock ring 232 and connecting neck 230 cooperate to rotationally couple housing portion 202 to the mounting base. Hall sensors 234 detect the rotational orientation based upon a magnetic field of a circular magnet 236. Based upon the position of an end user in the field of view and the rotational orientation of the housing portion 202, the image processor generates a command to apply current to the electromagnet to rotate housing portion 202 to a desired rotational orientation centered on the end user. In various embodiments, various processing resources may generate the command to apply current to electromagnet 250, such as the image processor, and audio processor, an MCU on the image processor printed circuit board or an MCU on the middle circuit board.

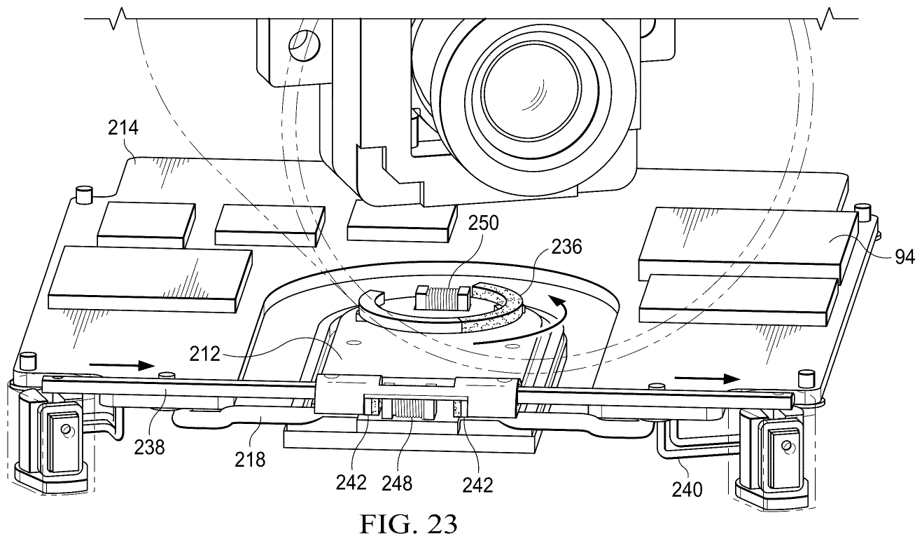

Referring now to FIG. 23, a front perspective transparent view depicts operation of a camera actuator synchronized with a microphone actuator to capture audiovisual of an end user in the camera field of view. Initially, an image sensor of the camera module detects an end user in one side of the camera field of view. In response, image processor 94 commands electromagnet 250 to generate a magnetic field that rotates the camera module housing portion towards the end user in the camera field of view. The electromagnet operates with repelling and attracting force on the circular magnet 236. As circular magnet 236 rotates with the housing portion, Hall sensor 234 on the middle circuit board 212 detect the rotational orientation and provides the rotational orientation for use in directing the microphones towards the end user. The Hall sensor feedback may be used to generate a proportional signal directly or the detected rotational orientation may be applied by a processor, such as an audio processor, to determine the speaker rotational orientation. Based upon the desired microphone orientation, a current is applied to electromagnet 248, which interacts with magnets 242 to laterally move connecting pushrod 238, thereby rotating the microphones about the fixing arm 240. As is described above, the camera rotational orientation may be set separate from the microphone orientation where the camera orientation is determined from visual image analysis and the microphone orientation is determined from capture audio analysis, such as to direct the speaker towards a selected of multiple people in the camera field of view.

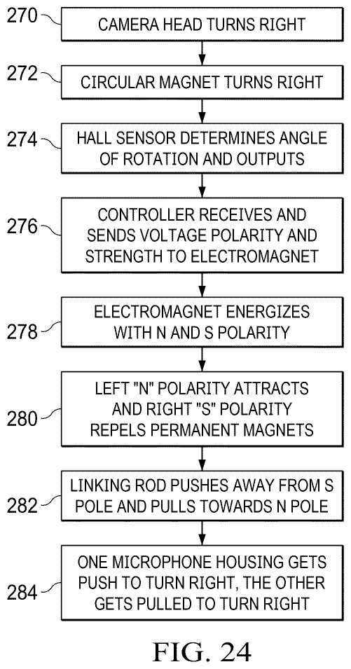

Referring now to FIG. 24, a flow diagram depicts a process for synchronizing camera and microphone rotation in a right direction. The process starts at step 270 with the camera module housing portion rotating right. At step 272 a circular magnet coupled to the housing portion rotates right with the housing portion. At step 274, a Hall sensor determines the angle of rotation and outputs it to a processing resource. At step 276 the processing resource receives the angle of rotation and sends a voltage polarity and strength to the electromagnet of the microphone. At step 278 the electromagnet energizes with north and south polarities based upon the current direction. At step 280 the left north polarity attracts and the right south polarity repels the permanent magnets of the connection pushrod. At step 282 the connecting pushrod pushes away from the south pole and pulls towards the north pole. At step 284 the process completes with one microphone pushed to rotate to the right and the other microphone pulled to rotate to the left.

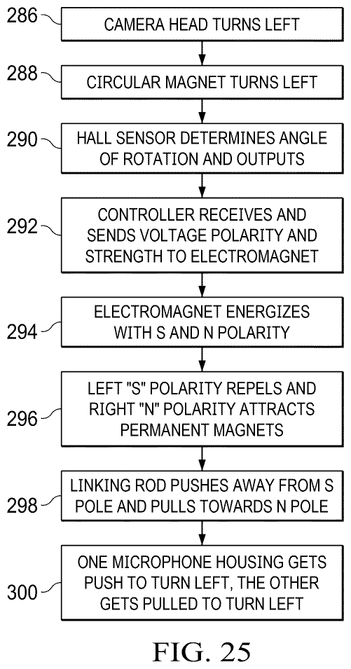

Referring now to FIG. 25, a flow diagram depicts a process for synchronizing camera and microphone rotation in a left direction. The process starts at step 286 with the camera module housing portion rotating left. At step 288 a circular magnet coupled to the housing portion rotates left with the housing portion. At step 290, a Hall sensor determines the angle of rotation and outputs it to a processing resource. At step 292 the processing resource receives the angle of rotation and sends a voltage polarity and strength to the electromagnet of the microphone. At step 294 the electromagnet energizes with north and south polarities based upon the current direction. At step 296 the right north polarity attracts and the left south polarity repels the permanent magnets of the connection pushrod. At step 298 the connecting pushrod pushes away from the south pole and pulls towards the north pole. At step 300 the process completes with one microphone pushed to rotate to the left and the other microphone pulled to rotate to the right.

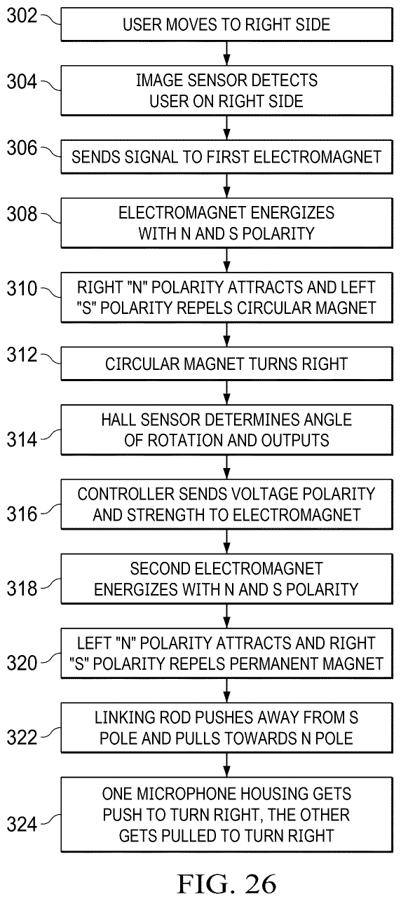

Referring now to FIG. 26, a flow diagram depicts a process for managing microphone orientation based upon a camera orientation. The process starts at step 302 when a user moves to a right side of the camera field of view. At step 304 an image sensor detects the end user in the right side of the camera field of view. At step 306 the image sensor sends a signal to the electromagnet of the camera actuator. At step 308 the electromagnet energizes with north and south polarities to rotate the camera in the direction that centers the end user in the field of view. At step 310 the right north polarity attracts and the left south polarity repels the circular magnet of the camera actuator so that at step 312 the circular magnet turns right. At step 314 the Hall sensor determines the angle of rotation and outputs the angle to the microphone actuator. At step 316 the processing resource of the microphone actuator sends a voltage polarity and strength to the electromagnet to induce rotation of the microphones in the direction of the end user. At step 318, the microphone actuator electromagnet energizes with north and south polarity. At step 320 the left north polarity attracts and the right south polarity repels the permanent magnets. At step 322 the connecting pushrod pushes away from the south pole and pulls towards the north pole. At step 324 the process completes with the microphones having one pushed to turn right and the other pulled to turn right.

Although the present invention has been described in detail, it should be understood that various changes, substitutions and alterations can be made hereto without departing from the spirit and scope of the invention as defined by the appended claims.

What is claimed is:

1. An information handling system comprising:
a processor operable to execute instructions to process information;
a memory interfaced with the processor and operable to store the instructions and information;
a display interfaced with the processor and operable to present the information as visual images; and
a camera coupled to a perimeter of the display by a bracket and interfaced with the processor, the camera having a housing coupled to the bracket by a mounting base, the housing containing a lens aligned with an image sensor to capture visual images in a field of view, the mounting base including a camera actuator coupled to the housing and operable to rotate the housing relative to the bracket.

2. The information handling system of claim 1 further comprising:
a first printed circuit board coupled in an interior of the bracket;
an image processor coupled to the first printed circuit board and interfaced with the image sensor; and
a second printed circuit coupled in the mounting base and interfaced with the camera actuator and the first printed circuit board, the image processor commanding the actuator to rotate the housing so that the field of view is directed at an end user captured in a visual image by the image sensor.

3. The information handling system of claim 2 wherein the camera actuator comprises:
a permanent magnet coupled to rotate with the camera housing; and
an electromagnet coupled to the second printed circuit board positioned to magnetically interact with the permanent magnet.

4. The information handling system of claim 3 further comprising:
a rotating member coupling the housing and the mounting base; and
the permanent magnet formed with a circular shape to rotate with the rotating member proximate the second printed circuit board.

5. The information handling system of claim 4 further comprising a Hall sensor coupled to the second circuit board and interfaced with the image processor to report a rotational orientation of the permanent magnet to the image processor.

6. The information handling system of claim 2 further comprising:
first and second microphones rotationally coupled to the bracket on opposite sides of the mounting base;
a connecting rod coupled between the first and second microphones; and
a microphone actuator coupled in the mounting base and operable to rotate the microphones in a synchronized manner with the housing.

7. The information handling system of claim 6 wherein the microphone actuator comprises:
an electromagnet coupled to the second circuit board in the mounting base proximate the connecting rod and interfaced with the image processor; and
a permanent magnet coupled to the connecting rod on opposing sides of the electromagnet.

8. The information handling system of claim 7 further comprising a sensor operable to detect a rotational position of the camera housing, the image processor applying the rotational position to direct the microphones in the direction of the field of view of the camera.

9. The information handling system of claim 7 further comprising a non-transient memory storing instructions that when executed on a processor determine the direction to audio detected by the microphones and command the microphone actuator to the direction of the audio independent of the camera rotational orientation.

10. A method for coupling directing a camera field of view towards an end user, the method comprising:
coupling a lens and image sensor in a housing;
coupling an image processor in an interior of a bracket;
coupling a camera actuator in a mounting base;
rotationally coupling the mounting base to the housing;
coupling the mounting base to the bracket;
detecting the end user with the image processor; and
commanding the camera actuator to rotate the housing to direct the field of view at the end user.

11. The method of claim 10 further comprising:
coupling a circular magnet to rotate with the housing;
coupling an electromagnet to a fixed location in the mounting base; and
actuating the camera actuator with a current applied to the electromagnet that interacts with the circular magnet.

12. The method of claim 11 further comprising:
coupling a Hall sensor in the mounting base proximate the circular magnet; and
detecting a rotational orientation of the housing by interaction of the circular magnet and the Hall sensor.

13. The method of claim 12 further comprising:
coupling first and second microphones in the bracket on opposite sides of the mounting base; and
rotating the microphones to align with the field of view.

14. The method of claim 10 further comprising:
rotationally coupling each microphone to the bracket;
coupling a pushrod between the microphones;
coupling an electromagnet in the mounting base proximate the pushrod; and
coupling a permanent magnet to the pushrod at each side of the electromagnet, the electromagnet rotating the microphones by moving the pushrod laterally.

15. The method of claim 14 further comprising:
detecting from the microphones a direction to an end user who is speaking; and
adjusting the direction of the microphones towards the end user who is speaking.

16. A camera comprising:
a housing;
a bracket having an interior, the bracket configured to couple to a display;
a lens coupled in the housing;
an image sensor coupled in the housing and aligned with a lens to capture visual images of the lens field of view;
an image processor coupled in the bracket interior;
a mounting base rotationally coupling the bracket to the housing; and
a camera actuator coupled in the mounting base and operable to rotate the housing relative to the bracket.

17. The camera of claim 16 wherein the camera actuator comprises:
a permanent magnet coupled to rotate with the camera housing; and
an electromagnet coupled to the mounting base to magnetically interact with the permanent magnet.

18. The camera of claim 17 further comprising:
a rotating member coupling the housing and the mounting base; and
the permanent magnet formed with a circular shape to rotate with the rotating member proximate the second printed circuit board.

19. The camera of claim 18 further comprising:
first and second microphones rotationally coupled to the bracket on opposite sides of the mounting base;
a connecting rod coupled between the first and second microphones; and
a microphone actuator coupled in the mounting base and operable to rotate the microphones in a synchronized manner with the housing.

20. The camera of claim 19 further comprising a sensor operable to detect a rotational position of the camera housing, the image processor applying the rotational position to direct the microphones in the direction of the field of view of the camera.
